(19) United States
(12) Patent Application Publication
(10) Pub. No.: US 2005/0082462 A1
(43) Pub. Date: Apr. 21, 2005

(54) Image pickup device

(75) Inventor: Tatsumi Yanai, Yokohama-shi (JP)

Correspondence Address: McDERMOTT, WILL & EMERY, 600 13th Street, N.W., Washington, DC, 20005-3096, US

(73) Assignee: NISSAN MOTOR CO., LTD.

(21) Appl. No.: 10/963,529

(22) Filed: Oct. 14, 2004

(30) Foreign Application Priority Data
Oct. 20, 2003 (JP) P2003-358693

(51) Int. Cl. H01L 27/00; H01J 3/14; H01J 5/16

(52) U.S. Cl. 250/208.1; 250/216

(57) ABSTRACT

An image pickup device is disclosed, having a plurality of camera modules each composed of a plurality of image pickup sections combined with normal image pickup lens components and associated image receiver sections, and operative to control image pickup directions and image pickup areas on individual image pickup sections in response to a control signal applied from an outside. Further, introducing an image processing section allows an image with an improved visibility to be obtained.

### BACKGROUND OF THE INVENTION

The present invention relates to image pickup devices using a plurality of image pickup sections to pickup an image of an object and, more particularly, to an image pickup device operative to pickup an image in a viewing region, at a dead angle for a driver, around surrounding areas of a moving object, such as a vehicle, or in a viewing region (both of these will be collectively referred to as an invisible viewing region) that is directly invisible.

Means for confirming an invisible viewing region for a driver around surrounding areas of a moving object, such as a vehicle, includes a method of picking up an image on the invisible viewing region using a wide-angle lens, or a method of picking up an image of an invisible viewing region using a plurality of independent cameras different in image pickup method as disclosed in Japanese Patent provisional Publication No. 2002-225629.

### SUMMARY OF THE INVENTION

However, the cameras each using the wide-angle lens are expensive and simultaneously apt to suffer from distortion in perspective and the method of locating the plural independent cameras requires a system structure that is apt to be complicated, resulting in issues in increased costs.

The present invention has an object to realize an image pickup device, in view of the foregoing issues, which is simple in a system structure and relatively low in cost and to provide an image pickup device comprising an image pickup system having a plurality of lens components and a plurality of image receiver sections located in correspondence to the plurality of lens components, a control signal input section inputting a control signal commanding the image pickup system to execute image pickup operation, an image-area selecting section responsive to the control signal inputted from the control signal input section to select a preset image area from image areas picked up by the image pickup system, and an image signal output section outputting an image signal indicative of an image area selected from the image-area selecting section.

### BRIEF DESCRIPTION OF THE DRAWINGS

FIG. 1 is a structural view of an image pickup device of a first embodiment.

FIG. 2 is a typical view for illustrating how an image is picked up with three image pickup sections that forms an image pickup system of the image pickup device of the first embodiment.

FIG. 3 is a view for illustrating the relationship between an arrangement, in a vehicle, of the image pickup system of the first embodiment and a viewing region that forms a dead angle of a driver.

FIGS. 4A and 4B are views for illustrating image-area selecting operation for selecting a given image area from an image pickup area in one image pickup section of the image pickup device of the first embodiment; FIG. 4A is a pixel information structural view in the relevant image pickup section; and FIG. 4B is a diagram illustrating operational sequence for executing image area selection to selectively extract a given image signal (indicative of the image area).

FIG. 5 is a flowchart showing operational process in image area selection of the first embodiment.

FIG. 6 is a structural view of an image pickup device of a second embodiment.

FIGS. 7A and 7B are views for illustrating image-area selecting operation for selecting a given image area from an image pickup area of two image pickup sections in the image pickup device of the second embodiment; FIG. 7A is a pixel information structural view in image receiving sections; and FIG. 7B is a diagram illustrating operational sequence for executing image area selection to selectively extract a given image signal (indicative of the image area).

FIG. 8 is a flowchart showing operational process in image area selection of the second embodiment.

FIG. 9 is a structural view of an image pickup device of a third embodiment.

FIGS. 10A and 10B are views for illustrating image-area selecting operation for setting a given image area based on image pickup areas of two image pickup sections in the image pickup device of the third embodiment; FIG. 10A is a pixel information structural view in image receiving sections; and FIG. 10B is a diagram illustrating operational sequence for executing image area selection to selectively extract a given image signal (indicative of the image area).

FIG. 11 is a flowchart showing operational process in image area selection of the third embodiment.

FIG. 12 is a structural view of an image pickup device of a fourth embodiment.

FIGS. 13A and 13B are views for illustrating image-area selecting operation for setting a given image area based on image pickup areas of two image pickup sections in the image pickup device of the fourth embodiment; FIG. 13A is a pixel information structural view in image receiving sections; and FIG. 13B is a diagram illustrating operational sequence for executing image area selection to selectively extract a given image signal (indicative of the image area).

FIG. 14 is a flowchart showing operational process in image area selection of the fourth embodiment.

### DETAILED DESCRIPTION OF THE PREFERRED EMBODIMENS

(First Embodiment)

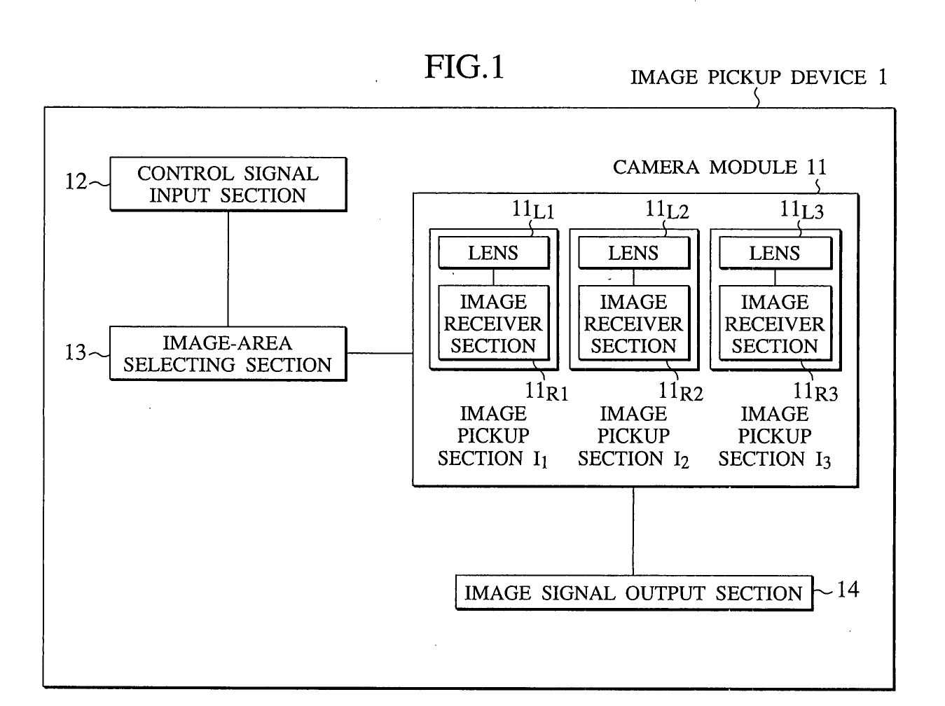

A fundamental structure of an image pickup device of a first embodiment according to the present invention is described with reference to a structural view shown in FIG. 1. As shown in FIG. 1, the image pickup device 1 of the first embodiment is comprised of a camera module 11, serving as an image pickup means (serving as an image pickup system), which is constituted by an array of image pickup sections I₁, I₂, I₃ comprised of general image pickup lens components 11_{L1}, 11_{L2}, 11_{L3} in three non-wide-angle lenses and three image receiver sections 11_{R1}, 11_{R2}, 11_{R3} in combination, a control signal input section 12, serving as a control signal input means, arranged to apply a control signal to the image pickup device upon automatically setting an image pickup direction and an image pickup area of the cameral module 21 in dependence on a traveling direction and a traveling speed of a moving object, such as a vehicle, or upon operation of a driver of the moving object, such as the vehicle, to manually set the image pickup direction and the image pickup area, an image-area selecting section 13, serving as an image area selection means, which is responsive to the control signal delivered from the control signal input section 12 for controlling individual image pickup directions and image pickup areas for selecting a given image pickup area, required for the driver, depending upon the image pickup area picked up by the camera module 11, and an image signal output section 14, serving as an image signal output means, which outputs an image signal related to the image area selected by the image-area selecting section 13.

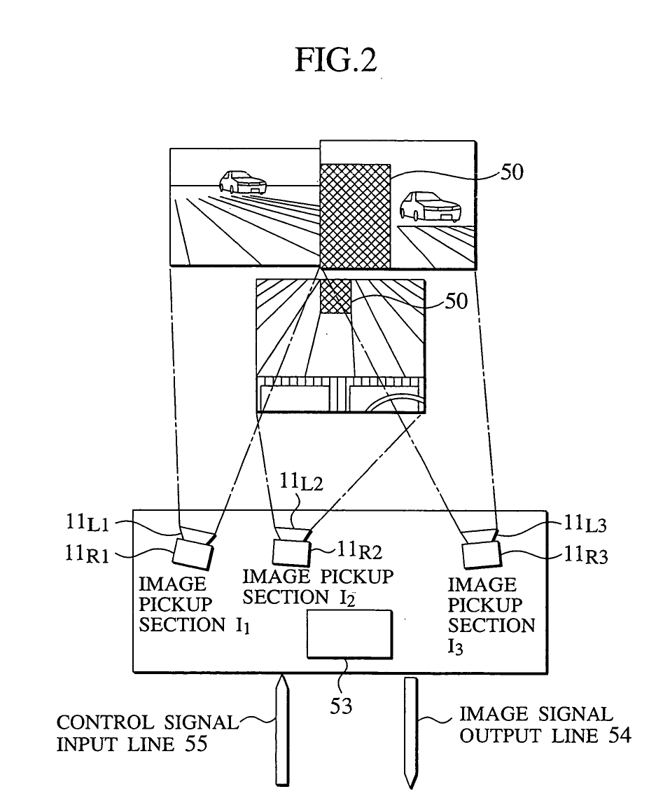

FIG. 2 is a schematic view illustrating a sharing status in image pickup areas of the respective image receiver sections 11_{R1}, 11_{R2}, 11_{R3} that constitute the image pickup system in the image pickup device 1. In general, a plurality of viewing regions exist, around surrounding areas of a moving object, such as a vehicle, which is invisible for the driver to need for acquiring information depending on surrounding circumferences. These correspond to viewing regions, such as vehicle forward side areas in entering an intersection with less visibility, vehicle rearward side areas in changing lanes, vehicle forward side lower areas in parallel-parking/narrow-road traveling, vehicle rearward side lower areas in backward parking and vehicle rearward lower areas in backward parking. As already described above, in the state-of-the-art, various attempts have heretofore been made to pickup images on the invisible viewing regions, which require to acquire information depending on surrounding circumferences, with a cameras using a wide-angle lens or a plurality of independent cameras.

As shown in FIG. 2, the image pickup device (serving as an image pickup system) of the present invention takes the form of a structure with a so-called multifaceted-eye type camera module having a plurality of image pickup sections. In particular, the image pickup system with such a multifaceted-eye type camera module is comprised of non-wide-angle lens components (generally available as image pickup lenses) 11_{L1}, 11_{L2}, 11_{L3} that cover minimum image areas required for picking up an image, image receiver sections 11_{R1}, 11_{R2}, 11_{R3}, a control signal input line 55, through which the control signal is applied, for setting image pickup conditions, such as an image pickup direction and an image pickup area for the image pickup sections I₁, I₂, I₃, comprised of the respective lens components 11_{L1}, 11_{L2}, 11_{L3} and the image receiver sections 11_{R1}, 11_{R2}, 11_{R3}, an image processing circuit 53 by which an image pickup area is extracted based on the control signal being applied, and an image signal output line 54 through which image information indicative of an extracted image is outputted. The multifaceted-eye type camera module, with such a structure, is enabled to have a higher pixel density than that of an ultra-wide-angle camera in a range of image pickup performances of image pickup cameras that are currently available in use. In using such a multifaceted-eye type camera module, the image pickup section 11_{R1} and the image pickup section 11_{R3} allow the driver to know a rear status of an object 50 in the presence of the object 50 disturbing eyesight in the image area of the image receiver section 11_{R2}. Accordingly, using such a multifaceted-eye type camera module makes it possible to provide an image, in an area required for the driver, as an image with a high quality at low costs. Further, such a multifaceted-eye type camera module is certainly modularized, thereby reducing issues of spoiling a beauty on an external appearance of a vehicle.

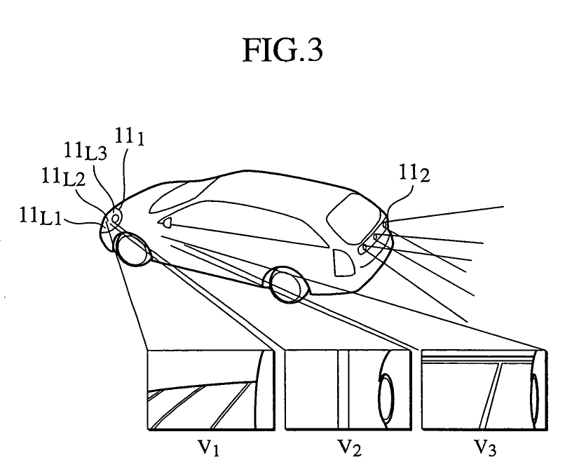

FIG. 3 is a view illustrating a mount example of the image pickup device of the present invention applied to a vehicle and showing the relationship between an arrangement, in a vehicle, of the camera modules of the current image pickup device and a viewing region that forms blind spots for a driver. In this example, in order to pickup images on the vehicle rearward side lower areas and the vehicle rearward lower areas, forming the viewing regions that are invisible for the driver during backward parking of the vehicle, the multifaceted-eye type camera modules 11₁, 11₂ are located on the vehicle at a sidewise forward position thereof, in opposition to the driver of the vehicle, and a vehicle rearward position, respectively. With the camera modules mounted on such locations, the respective image pickup sections I₁, I₂, I₃, forming the image pickup system of the camera module 11₁, are enabled to pickup images as shown by V₁, V₂, V₃, respectively, providing a capability of covering the viewing regions that are invisible for the driver.

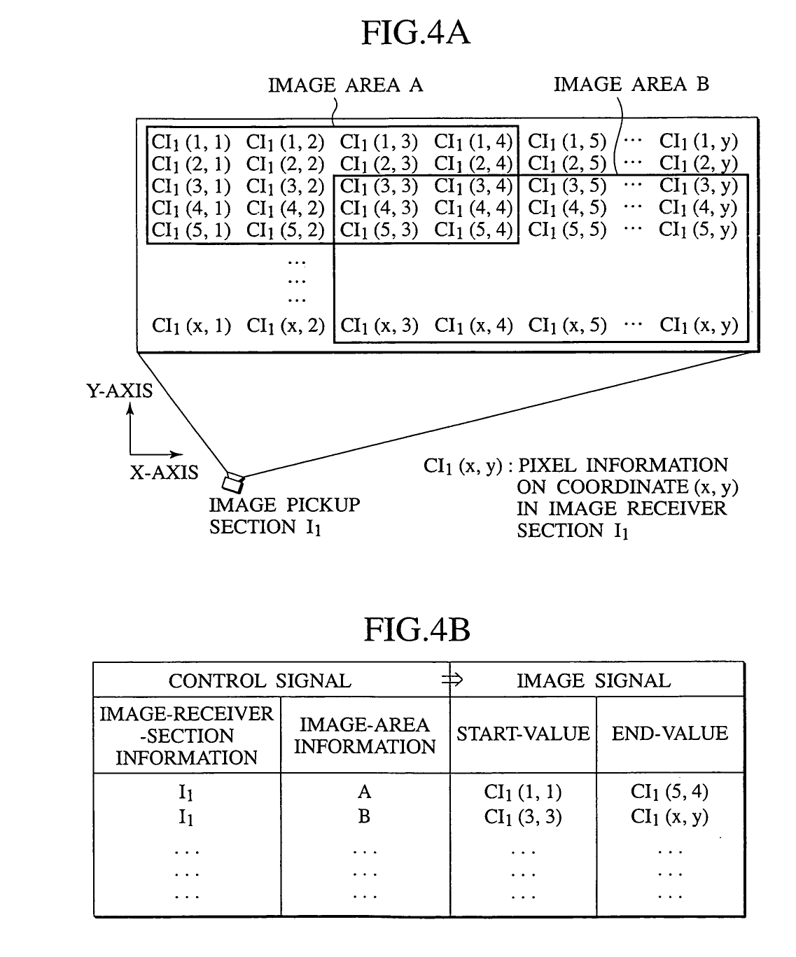

FIG. 4A is a pixel information structural view for illustrating an operational process to execute image area selection for selecting a given image area from a pickup image area resulting from one image receiver section (such as the image receiver section I₁) among the three image receiver sections, by which the camera module 11 is constituted, and showing an arrangement status of pixel information in the image pickup section I₁. Here, C₁₁ (x, y) represents pixel information on a coordinate (x, y) of the image receiver section I₁ wherein a transverse direction (which is not necessarily a horizontal direction on a solid line) within the pickup image area is plotted on an X-axis and a vertical direction (which is not necessarily a vertical direction on a solid line) within the pickup image area is plotted on a Y-axis. The image pickup area is preliminarily prepared with a plurality of image areas (such as an image area A and image area B in FIG. 4A) that will be required under various situations.

FIG. 4B is a diagram for illustrating an operational process for image area selection for selectively extracting a given image signal from the camera module under a situation where the camera module is applied with control signals, including image-receiver-section information (information representing which of the image receiver section among the image receiver sections forming the image pickup device is allocated) and image-area information indicative of individual image areas. As shown in FIG. 4B, if the camera module 11 is applied with the control signals, including image-receiver-section information and image-area information (which will be referred to as image-receiver-section/image-area information: such as image-receiver-section I₁/image-area A) from the control signal input line 55, the cameral module 11 selects pixel information (with a start-value C₁₁ (1, 1)/end-value C₁₁ (5, 4)) of the image area in the image receiver section I₁ corresponding to the control signal applied to the camera module 11 and outputs this image information to the image signal output line 54.

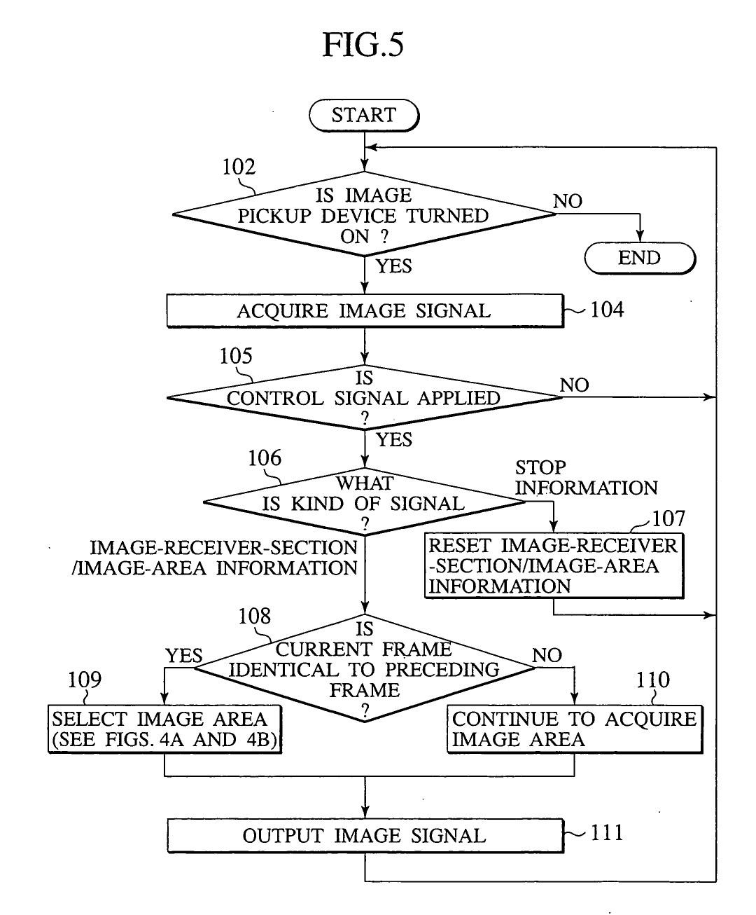

FIG. 5 is a flowchart illustrating an operational process for performing the above image area selection in the first embodiment. First, in step S102, discrimination is made to find whether the image pickup device 1 is turned on or turned off by the driver. If discrimination is made in this step that the image pickup device 1 is turned on by the driver, the operation proceeds to step S104. In step S104, the camera module 11, shown in FIG. 1, picks up an image of a viewing region, which is invisible for the driver, an image signal and, then, the operation proceeds to step 105. On the contrary, if discrimination is made in step 102 that the image pickup device 1 is turned off by the driver, a series of operational flows are terminated. Then, in step 105, discrimination is made to find whether the camera module 11 is applied with control signals by which receiver-section information and image area are set. If discrimination is made in this step that the control signals are applied to the cameral module 11, the operation proceeds to step 106. In step 106, discrimination is made to find whether a kind of applied control signal is stop information or Image-receiver-section/image-area information. If discrimination is made in this step that the applied control signal is image-receiver-section/image-area information, the operation proceeds to step 108. On the contrary, if discrimination is made that the control signal applied in step 106 is stop information, the operation proceeds to step 107. In step 107, image-receiver-section/image-area information, which is applied in a preceding stage, is reset and, then, the operation is routed back to step 102. In step 108, discrimination is made to find whether the current image area is identical to the preceding image area. If discrimination made in this step that the current image area is different from the preceding image area (that is, in a case where “new image area” appears), the operation proceeds to step 109. In step 109, after the image area is selected in accordance with the operational process shown in FIG. 4, the operation proceeds to step 111. In contrast, if discrimination made in step 108 that the current image area is identical to the preceding image area, the operation proceeds to step 110. In step 110, no replacement of image-area information is carried out to continuously acquire current image-area information and the operation proceeds step 111. Then, an image signal is outputted in step 111 and the operation is routed back to step 102.

Thus, with the first embodiment, no plurality of pieces of independent cameras are individually arranged to allow a plurality of image pickup sections to be constituted on a level of component parts for thereby providing an integrated image pickup system and an image pickup device as a whole is enabled to use an electric power supply section and a case in common use, to achieve a simplification in a unit scale, resulting in realization of low cost production.

(Second Embodiment)

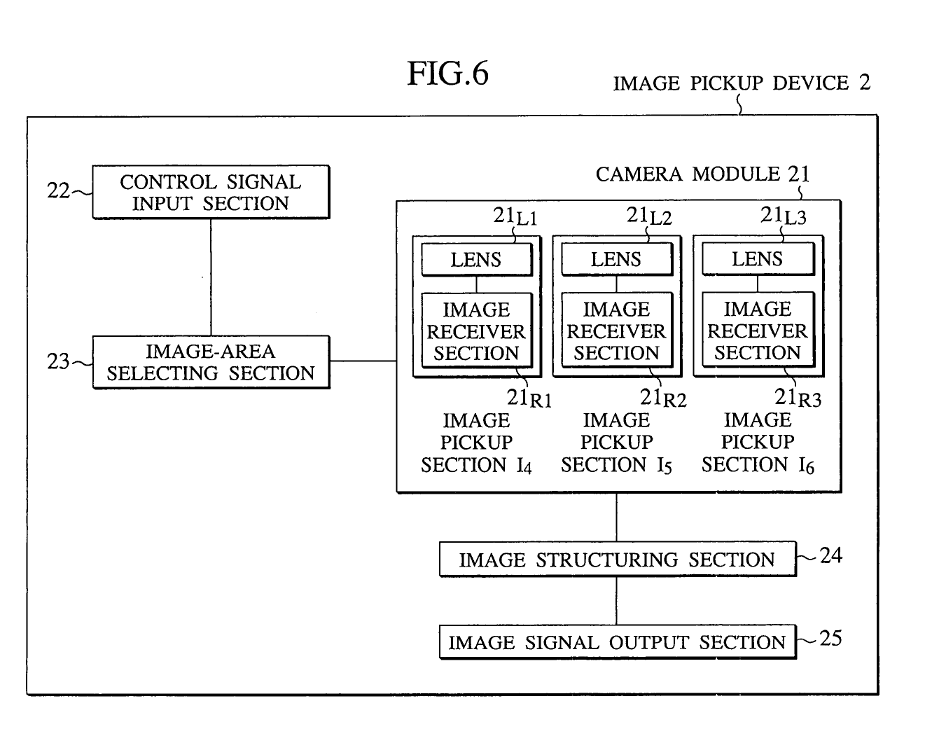

A fundamental structure of an image pickup device of a second embodiment according to the present invention is described with reference to a structural view shown in FIG. 6.

As shown in FIG. 6, the image pickup device 2 of the second embodiment is comprised of a camera module 21, serving as an image pickup means (serving as an image pickup system), which is constituted by an array of image pickup sections I₄, I₅, I₆ comprised of general image pickup lens components 21_{L1}, 21_{L2}, 21_{L3} in three non-wide-angle lenses and three image receiver sections 21_{R1}, 21_{R2}, 21_{R3} in combination, a control signal input section 22, serving as a control signal input means, arranged to apply control signals to the image pickup device upon automatically setting an image pickup direction and an image pickup area of the cameral module 21 in dependence on a traveling direction and a traveling speed of a moving object, such as a vehicle, or upon operation of a driver of the moving object, such as the vehicle, to manually set the image pickup direction and the image pickup area, an image-area selecting section 23, serving as an image area selection means, which is responsive to the control signals delivered from the control signal input section 22 for controlling individual image pickup directions and image pickup areas for selecting a given image pickup area, needed for the driver, depending upon pickup image areas resulting from the camera module 21, an image structuring section 24, serving as an image structuring means, by which one image area is defined from the plurality of image areas selected from the plural image receiver sections that form the camera module 21, and an image signal output section 25, serving as an image signal output means, which outputs an image signal indicative of the image area synthesized by the image structuring section 24.

Also, with the presently filed embodiment, while the camera module (serving as an image pickup system) is comprised of the three image pickup sections I₄, I₅, I₆, it doesn't matter if the number of pieces of the image pickup sections lies in a desired number of pieces (in plural pieces).

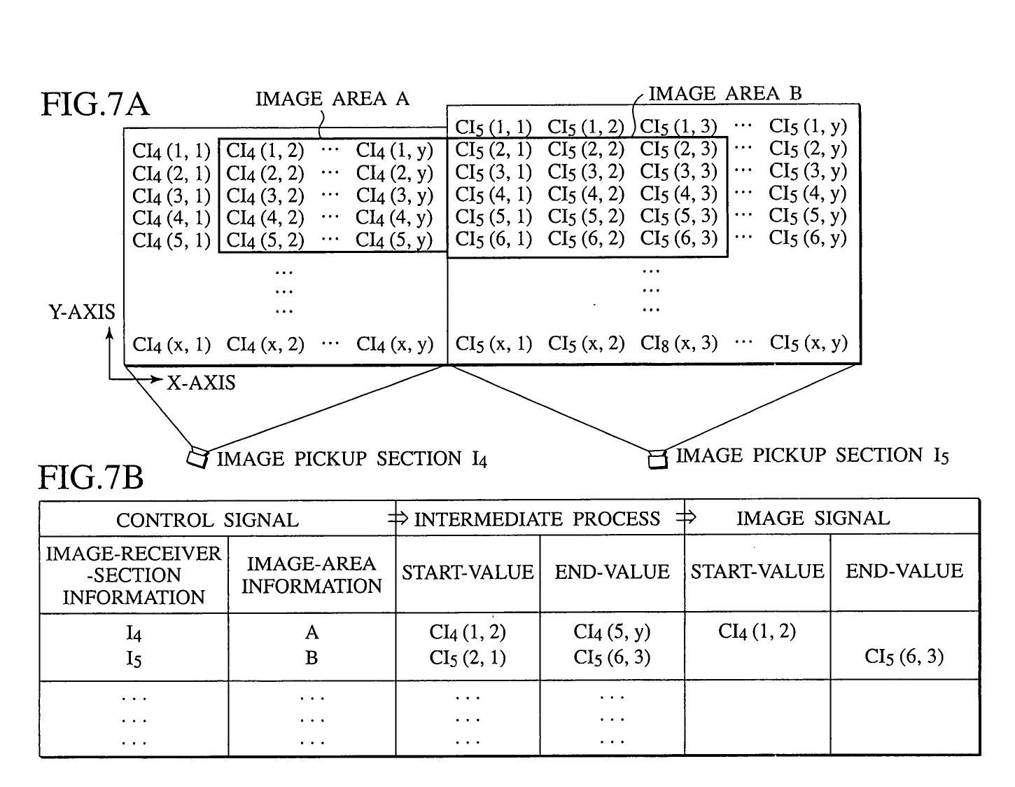

FIG. 7A is a pixel information structural view for illustrating an operational process to execute image area selection in which a given image area is selected from the pickup image areas resulting from two image receiver sections (such as the image receiver section I₄ and the image receiver section I₅) among the three image receiver sections, by which the camera module 21 is constituted, and showing an arrangement status in pixel information of the image receiver section I₄ and the image receiver section I₅. Like in FIGS. 4A and 4B, C₁₄ (x, y) and C₁₅ (X, y) represent pixel information wherein a transverse direction (which is not necessarily an actual horizontal direction) within the pickup image area is plotted on an X-axis and a vertical direction (which is not necessarily an actual vertical direction) within the pickup image area is plotted on a Y-axis. Each pickup image area is preliminarily prepared with a plurality of image areas (such as an image area A and image area B in FIG. 7A) that will be required on various situations.

FIG. 7B is a diagram for illustrating an operational process to execute image area selection for selectively extracting a given image signal from the camera module when the camera module is applied with control signals, including image-receiver-section information (representing which of the image receiver section among the image receiver sections that form the image pickup device is allocated) and image-area information indicative of individual image areas. As shown in FIG. 7B, first, the camera module 21 is applied with the control signals, including two sets (in the form of “image-receiver-section I₄/image-area A” and “image-receiver-section I₅/image-area B” in such a case) of image-receiver-section/image-area information, from the control signal input line 55 (see FIG. 2). Then, in intermediate process, the camera module 21 is responsive to image-receiver-section/image-area information to select the following pixel information that includes: (1) for an image area A, pixel information with a start-value C₁₄ (1, 2)/end-value C₁₄ (5, y); and (2) for an image area B, pixel information with a start-value C₁₅ (2, 1)/end-value C₁₅ (6, 3). Then, the image structuring section 24 is responsive to these image areas to define one pixel information with the start-value C₁₄ (1, 2)/end-value C₁₅ (6, 3) and thereafter, provides the image signal output line 54 (see FIG. 2) with image-area information synthesized in such a way to allow the image area A and the image area B to be juxtaposed on a single screen.

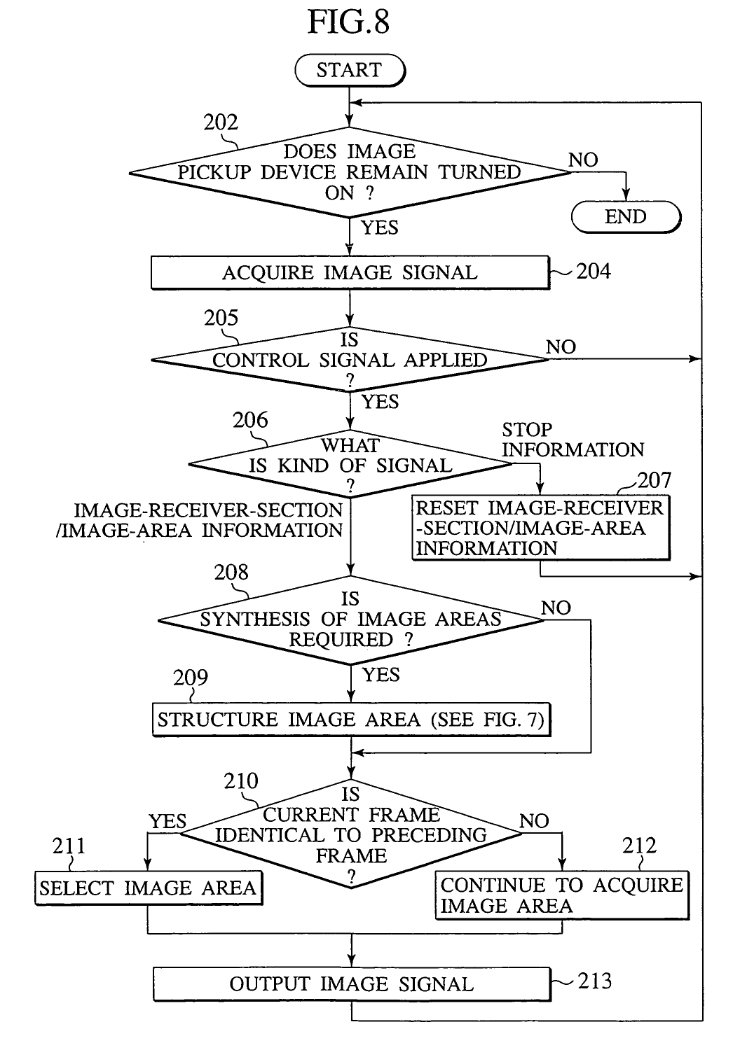

FIG. 8 is a flowchart illustrating an operational process to execute image area selection, set forth above, of the second embodiment.

First in step 202, discrimination is made to find whether a driver turns the image pickup device 2 on. If in this step, discrimination is made that the driver turns the image pickup device 2 on, then, the operation is routed to step 204. In step 204, the camera module 21, shown in FIG. 6, picks up a viewing region, which is invisible for the driver, as an image signal and then, the operation is routed to step 205. On the contrary, if in step 202, discrimination is made that the driver turns the image pickup device 2 off, then, a series of operational flows is terminated. In next step 205, discrimination is made to find whether the camera module 21 is applied with the control signals for setting image-receiver-section information and the image area. If in this step, discrimination is made that the control signal is applied, the operation is routed to step 206. In step 206, discrimination is made to find whether a kind of the control signal being applied is image-receiver-section/image-area information. If in this step, discrimination is made that the applied control signal is image-receiver-section/image-area information, the operation is routed to step 208. In contrast, if discrimination is made that the control signal applied in step 206 is a stop signal, then, the operation is routed to step 207. In step 207, image-receiver-section/image-area information, which has been retrieved in a preceding stage, is reset and thereafter, the operation is routed back to step 202. Next, in step 208, discrimination is made whether to synthesize the image area A (image area selected from the pickup image area in the image receiver section 1₄) and the image area B (image area selected from the pickup image area in the image receiver section 1₅) in FIGS. 7A and 7B. If in this step, discrimination is made that there is a need for synthesizing the image areas, the operation is routed to step 209. On the contrary, if in this step, discrimination is made that no need arises for synthesizing the image areas, the operation is routed to step 210. Next, in step 209, the image structuring section 24 executes the operation in the operational process shown in FIGS. 7A and 7B to synthesize image information such that the image area A and the image area B are juxtaposed on a single screen. In consecutive step 210, discrimination is made to find whether the current image area is identical to a preceding image area. If in this step, discrimination is made that the current image area is different (in case of a “new image area”) from the preceding image area, the operation is routed to step 211. In step 211, replacement operation is executed the replacement of current image-area information into new image-area information and thereafter, the operation is routed to step 213. On the contrary, if in step 211, discrimination is made that the current image area is identical to the preceding image area, the operation is routed to step 212. In step 212, no replacement of image-area information is executed while continuously acquiring current image-area information and thereafter, the operation is routed to step 213. Then, in step 213, the operation is executed to output the image signal and the operation is routed back to step 202.

Thus, with the second embodiment, due to the provision of the image structuring means by which the plural image areas selected from the plurality of image receiver sections are synthesized into a single image area, in addition to the same advantages as those of the first embodiment, another advantage results in for the operation to be enabled to output image areas in a wide range with a favorable visibility.

(Third Embodiment)

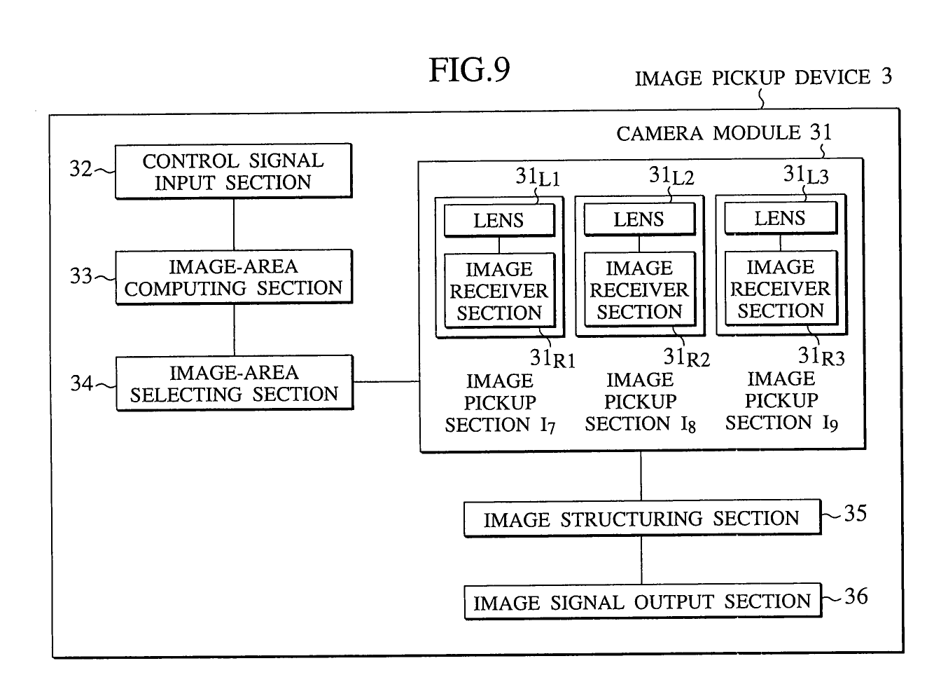

A fundamental structure of an image pickup device of a third embodiment according to the present invention is described with reference to a structural view of FIG. 9.

As shown in FIG. 9, the image pickup device 3 of the third embodiment is comprised of a camera module 31, serving as an image pickup means (serving as an image pickup system), which is constituted by an array of image pickup sections I₇, I₈, I₉ comprised of general image pickup lens components 31_{L1}, 31_{L2}, 31_{L3} in three non-wide-angle lenses and three image receiver sections 31_{R1}, 31_{R2}, 31_{R3} in combination, a control signal input section 32, serving as a control signal input means, for applying the image pickup device with control signals upon automatically setting an image pickup direction and an image pickup area of the cameral module 31 in dependence on a traveling direction and a traveling speed of a moving object, such as a vehicle, or upon operation of a driver of the moving object, such as the vehicle, for manually setting the image pickup direction and the image pickup area, an image-area computing section 33, serving as an image area computation means, which is operative to compute and determine an image area required for the driver in response to the control signals delivered from the control signal input section 32, an image-area selecting section 34, serving as an image area selection means, for selecting the above image area from picked-up image areas resulting from the camera module 31 upon controlling the image pickup direction and the image areas for the individual image pickup sections in response to the image area calculated by the image-area computing section 33, an image structuring section 35, serving as an image structuring means, that structures one image area from the plurality of image areas selected from the plurality of image receiver sections forming the camera module 31, and an image signal output section 35, serving as an image signal output means, which outputs an image signal indicative of an image area synthesized by the image structuring section 35.

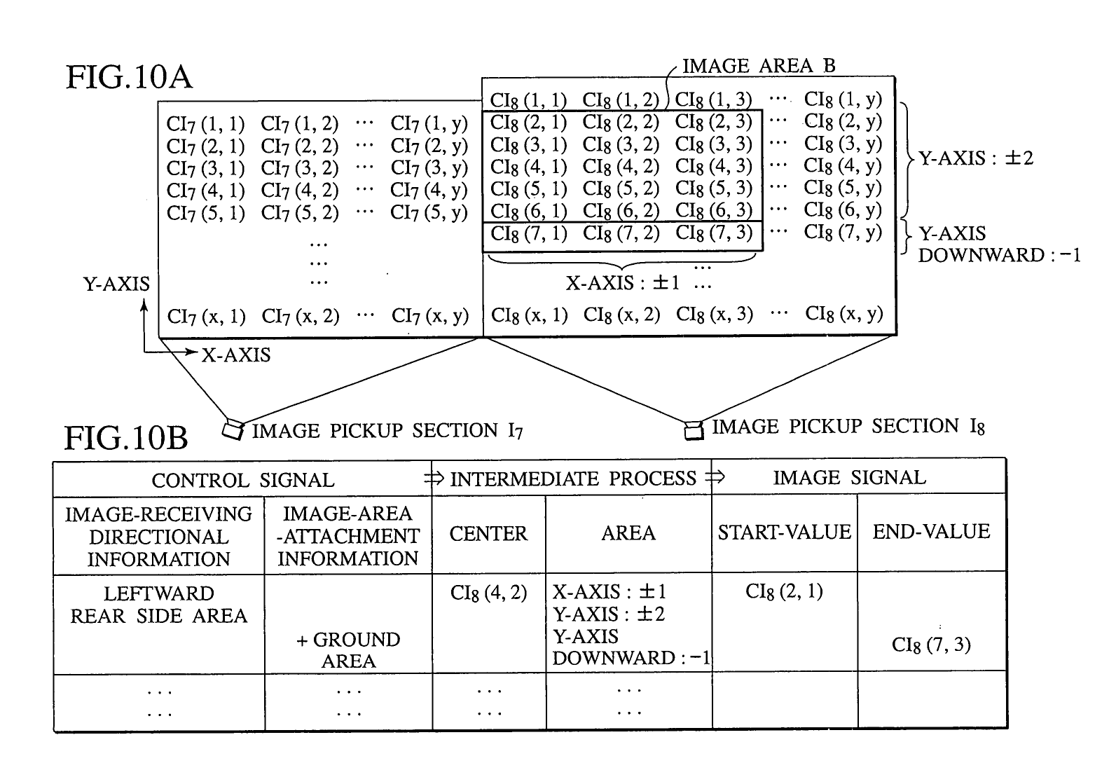

FIG. 10A is a pixel information structural view for illustrating an operational process to execute image area selection in selecting a given image area from the image pickup areas of two image receiver sections (such as the image receiver section I₇ and the image receiver section I₈) among the three image receiver sections, by which the camera module 31 is constituted, and showing an arrangement status of pixel information in the image receiver section I₇ and the image receiver section I₈. Like in FIGS. 7A and 7B, C₁₇ (x, y) and C₁₈ (x, y) represent pixel information related to a coordinate system (x, y) of the image receiver section I₇ and a coordinate system (x, y) of the receiver section I₈ wherein a transverse direction (which is not necessarily an actual horizontal direction) within the image pickup area is plotted on an X-axis and a vertical direction (which is not necessarily an actual vertical direction) within the image pickup area is plotted on a Y-axis. It is supposed that the image pickup areas are preliminarily provided with a plurality of image areas required under various situations.

FIG. 10B is a diagram for illustrating a sequence of executing image area selection for selectively extracting a given image signal from the camera module upon receipt of control signals, including image-receiver-section information (representing which of the image receiver section among the image receiver sections that form the image pickup system is allocated), image-area information indicative of individual image areas and image-area-attachment information (hereinafter referred to as image-receiver-section/image-area/image-area-attachment information). As shown in FIG. 10B, first, the camera module 31 is applied with the control signals, including two sets (image-receiver-section I₇/image-area A and image-receiver-section I₈/image-area B in this case) of image-receiver-section/image-area information (indicative of image directional information) and image-area-attachment information, from the control signal input line 55 (see FIG. 2). In this example, the image pickup direction is selected to include a leftward rear side area and image-area-attachment information is selected to include a ground area. Then, in intermediate process, the image-area computing section 33 is responsive to these control signals, which are applied, to calculate a center pixel C₁₈ (4, 2) and, on the basis of this center pixel, calculate an area on X-axis: ±1, Y-axis: ±2 and a Y-axis downward: −1. Then, the image structuring section 35 is responsive to these calculated values for synthesizing image-area information and image-area-attachment information into one image area (with a start-value C₁₈ (2, 1)/end-value C₁₈ (7, 3)) and, subsequently, outputs synthesized image information to the image signal output line 54 (see FIG. 2).

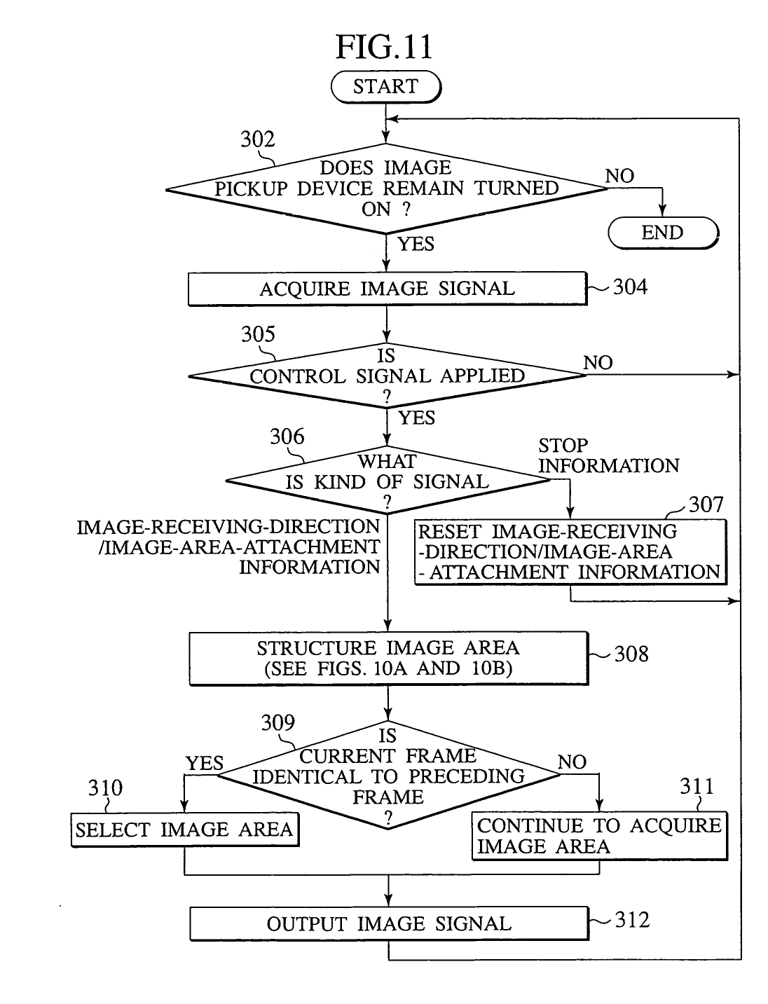

FIG. 11 is a flowchart illustrating an operational process to execute the above-described image-information-area selection of the third embodiment. First in step 302, discrimination is made to find whether a driver turns the image pickup device 3 on. If in this step, discrimination is made that the driver turns the image pickup device 3 on, then, the operation is routed to step 304. In step 304, the camera module 31, shown in FIG. 9, picks up a viewing region, which is invisible for the driver, to acquire an image signal and, then, the operation is routed to step 305. On the contrary, if in step 302, discrimination is made that the driver turns the image pickup device 3 off, then, a series of operational flows is terminated. Next, in step 305, discrimination is made to find whether the camera module 31 is applied with control signals for setting image-receiver-section information, an image area and image-area-attachment information.

If in this step, discrimination is made that these control signals are inputted, the operation is routed to step 306. In step 306, discrimination is made to find whether a kind of the inputted control signal includes stop information or image-receiver-section/image-area/image-area-attachment information. If in this step, discrimination is made that the inputted control signal includes image-receiver-section/image-area/image-area-attachment information, the operation is routed to step 308. In contrast, if discrimination is made that the control signal applied in step 306 includes a stop signal, then, the operation is routed to step 307. In step 307, image-receiver-section/image-area/image-area-attachment information, which has been retrieved in a preceding stage, is reset and thereafter, the operation is routed to step 302. Upon executing step 308 for synthesizing the image area and image-area-attachment information based on image-receiver-section/image-area/image-area-attachment information in the processing method shown in FIGS. 10A and 10B, the operation is routed to step 309. Then, in step 309, discrimination is made to find whether the synthesized image area is identical to the preceding image area. If in this step, discrimination is made that the synthesized image area is different (in case of a “new image area”) from the preceding image area, the operation is routed to step 310. In step 310, replacement operation is executed to effectuate the replacement of the image area into the new image-area information and thereafter, the operation is routed to step 312. On the contrary, if in step 309, discrimination is made that the image area is identical to the preceding image area, the operation is routed to step 311. In step 311, no replacement of image-area information is executed to continue the acquiring of current image-area information and thereafter, the operation is routed to step 312. Then, in step 312, the operation is executed to output the image signal and the operation is routed back to step 302.

Thus, with the third embodiment, due to the structure including the image area computation means that computes and determines the image area that is preliminarily set in a manual or automatic fashion as set forth above, in addition to the same advantages as those of the first embodiment, another advantage results in where it becomes possible to set image areas, which are required for the driver, in a favorable flexibility.

(Fourth Embodiment)

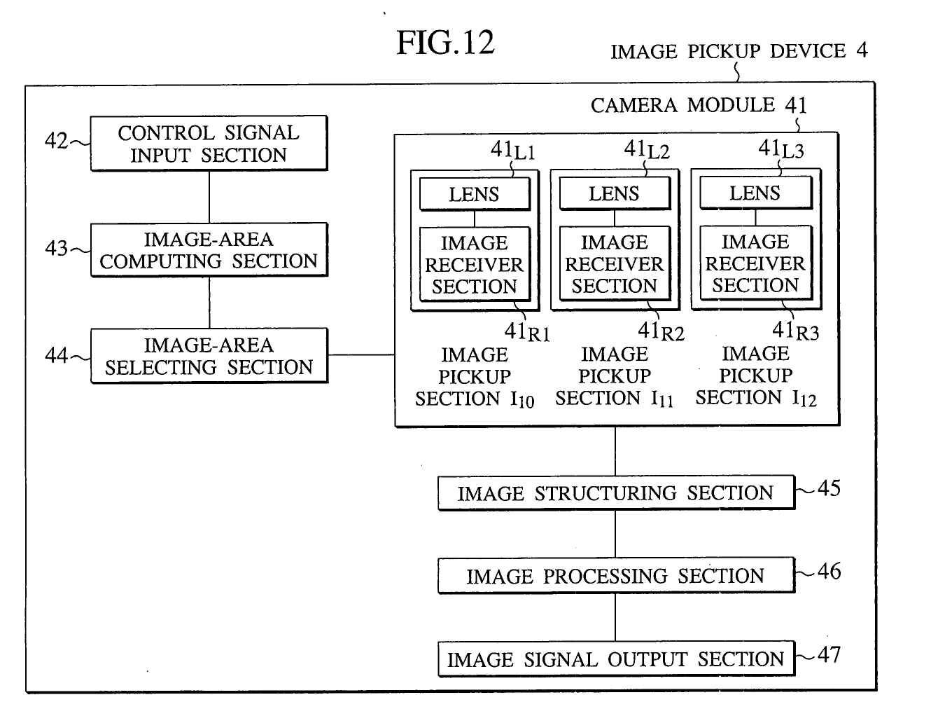

A fundamental structure of an image pickup device of a third embodiment according to the present invention is described with reference to a structural view of a structural view of FIG. 12.

As shown in FIG. 12, the image pickup device 4 of the fourth embodiment is comprised of a camera module 41, serving as an image pickup means (serving as an image pickup system), which is constituted by an array of image pickup sections I₁₀, I₁₁, I₁₂ comprised of general image pickup lens components 1_{L1}, 41_{L2}, 41_{L3} in three non-wide-angle lenses and three image receiver sections 41_{R1}, 41_{R2}, 41_{R3} in combination, a control signal input section 42, serving as the control signal input means, for applying the image pickup device with control signals upon automatically setting an image pickup direction and an image pickup area of the cameral module 41 in dependence on a traveling direction and a traveling speed of a moving object, such as a vehicle, or upon operation of a driver of the moving object, such as the vehicle, for manually setting the image pickup direction and the image pickup area, an image-area computing section 43, serving as an image-area computation means, which is responsive to the control signals delivered from the control signal input section 42 for computing and determining the image area, required for the driver, depending upon the control signals delivered from the control signal input section 42, an image-area selecting section 44, serving as an image area selection means, for selecting the above image area from picked-up image areas resulting from the camera module 41 upon controlling the image pickup directions and the image areas for the individual image pickup sections in response to the image area calculated by the image-area computing section 43, an image structuring section 45, serving an as image structuring means, that structures one image from the plurality of image areas selected from the plurality of image receiver sections forming the camera module 41, an image processing section 46, serving as an image processing means, which executes image processing required for the driver to have an improved visibility on a screen, and an image signal output section 47, serving as an image signal output means, which outputs an image signal representing an image area whose image is processed by the image processing section 46.

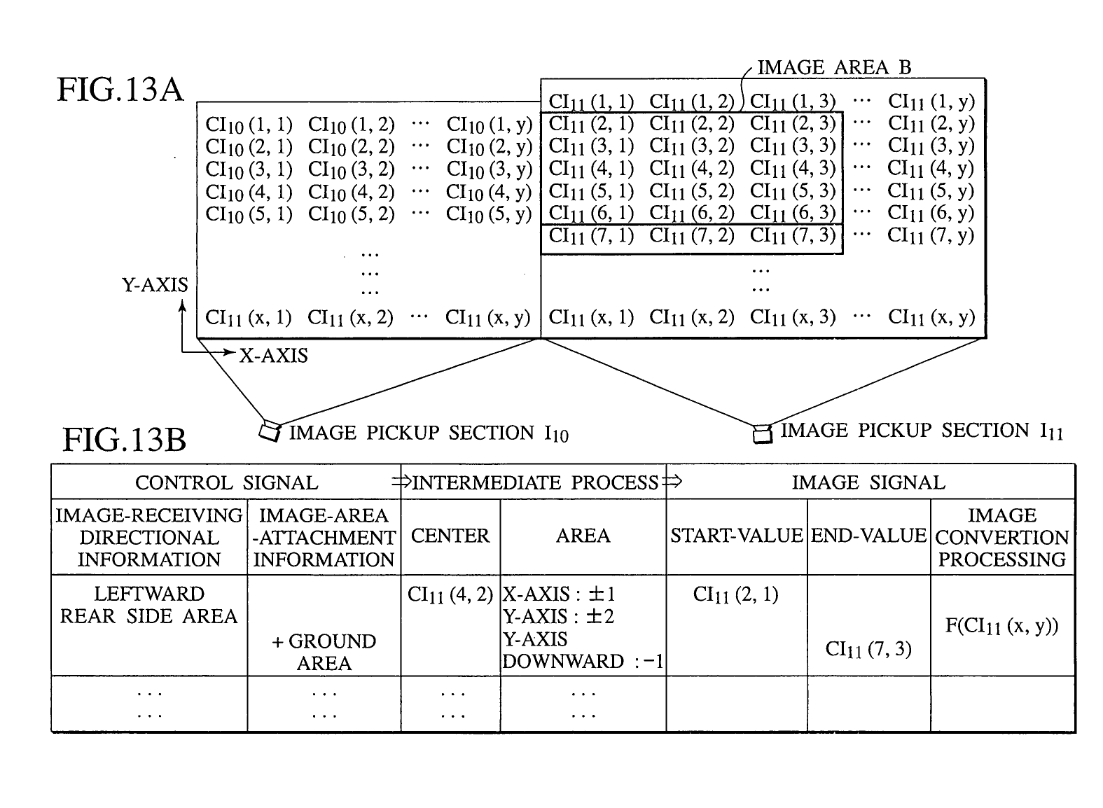

FIG. 13A is a pixel information structural view for illustrating an operational process to execute image area selection in selecting a given image area from image pickup areas of two image receiver sections (such as the image receiver section I₇ and the image receiver section I₈) among the three image receiver sections, by which the camera module 31 is constituted, and showing an arrangement status of pixel information in the image receiver section I₇ and the image receiver section I₈. Like in FIGS. 10A and 10B, C₁₇ (x, y) and C₁₈ (x, y) represent pixel information related to a coordinate system (x, y) of the receiver section I₇ and a coordinate system (x, y) of the receiver section I₈ wherein a transverse direction (which is not necessarily an actual horizontal direction) within the image pickup area is plotted on an X-axis and a vertical direction (which is not necessarily an actual vertical direction) within the image pickup area is plotted on a Y-axis. It is supposed that the image pickup areas are preliminarily provided with a plurality of image areas required under various situations.

FIG. 13B is a diagram for illustrating a sequence of executing image area selection for selectively extracting a given image signal from the camera module upon receipt of control signals, including image-receiver-section information (representing which of the image receiver section among the image receiver sections, which form the image pickup system, is allocated), image-area information indicating individual image areas and image-area-attachment information (hereinafter referred to as image-receiver-section/image-area/image-area-attachment information) to be attached to these image area information. As shown in FIG. 13B, first, the camera module 31 is applied with control signals, including two sets (image-receiver-section I₇/image-area A and image-receiver-section I₈/image-area B in this case) of image-receiver-section/image-area information (image directional information) and image-area-attachment information to command areas to be added to these image area information, from the control signal input line 55 (see FIG. 2). In this example, the image pickup direction is selected to include a leftward rear side and image-area-attachment information is selected to include a ground area. Then, in intermediate process, the image-area computing section 33 responds to these inputted control signals to calculate a center pixel C₁₁₁ (4, 2) and, on the basis of this center pixel, calculate an area with X-axis: ±1, Y-axis: ±2 and a Y-axis downward: −1. Then, the image structuring section 45 synthesizes image-area information and image-area-attachment information into one image area (with start-value C₁₁₁ (2, 1)/end-value C₁₁₁ (7, 3)) based on the above-described calculated values. Subsequently, upon operation of the image processing section 46 to executes actual image processing for improving image qualities, such as brightness/contrast adjustment, a moving average for each pixel and conversion in visual point, picture image information, whose image is processed, is outputted to the image signal output line 54 (see FIG. 2).

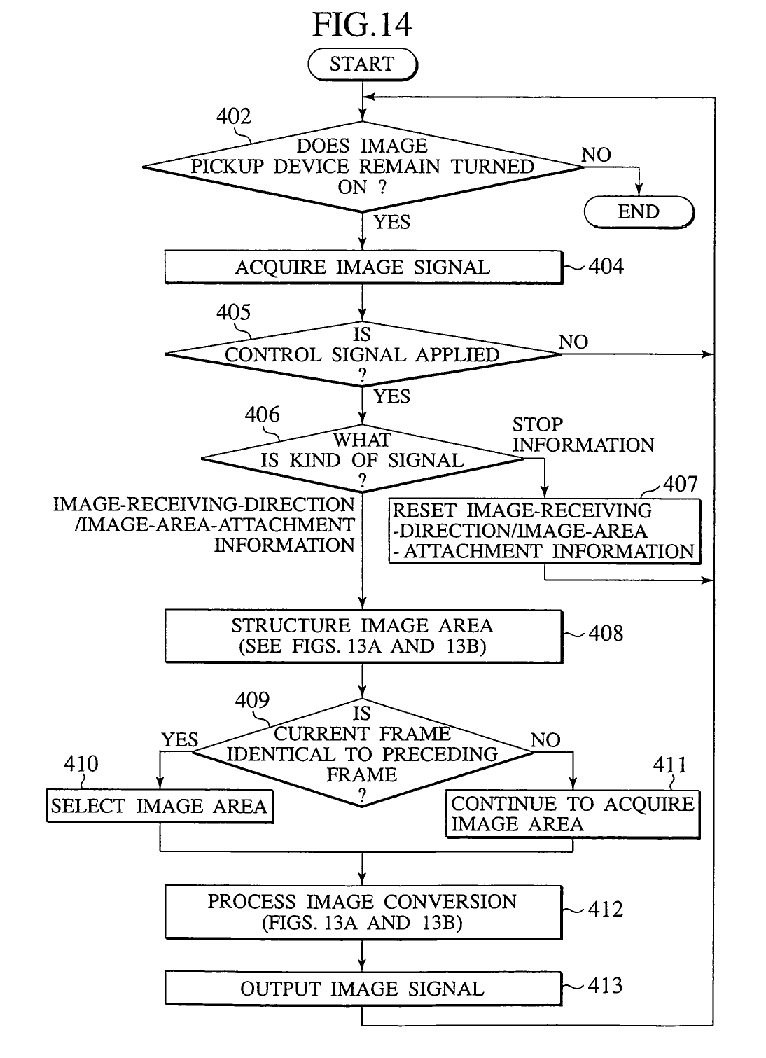

FIG. 14 is a flowchart illustrating an operational process on the above-described image information area selection of the fourth embodiment.

First in step 402, discrimination is made to find whether a driver turns the image pickup device 4 on. If in this step, discrimination is made that the driver turns the image pickup device 4 on, then, the operation is routed to step 404. In step 404, the camera module 41, shown in FIG. 12, picks up a viewing region, which is invisible for a driver, as an image signal and, then, the operation is routed to step 405. On the contrary, if in step 402, discrimination is made that the driver turns the image pickup device 4 off, then, a series of operational flows is terminated. In next step 405, discrimination is made to find whether the camera module 41 is applied with control signals for setting image-receiver-section information, an image area and image-area-attachment information. If in this step, discrimination is made that the control signals are applied, the operation is routed to step 406. In step 406, discrimination is made to find whether a kind of the inputted control signal includes stop information or image-receiver-section/image-area/image-area-attachment information. If in this step discrimination is made that the inputted control signal includes image-receiver-section/image-area/image-area-attachment information, the operation is routed to step 408. In contrast, if discrimination is made that the control signal applied in step 406 includes the stop signal, then, the operation is routed to step 407.

In step 407, image-receiver-section/image-area/image-area-attachment information, which has been retrieved in a preceding stage, is reset and thereafter, the operation is routed to step 402. In step 408, upon synthesizing the image area and image-area-attachment information based on image-receiver-section/image-area/image-area-attachment information in the processing method shown in FIGS. 13A and 13B, the operation is routed to step 409. Then, in step 409, discrimination is made to find whether the synthesized image area is identical to the preceding image area. If in this step, discrimination is made that the synthesized image area is different (in case of a “new image area”) from the preceding image area, the operation is routed to step 410. In step 410, replacement operation of the image area into the new image-area information is executed and thereafter, the operation is routed to step 412. On the contrary, if in step 409, discrimination is made that the synthesized image area is identical to the preceding image area, the operation is routed to step 411. In step 411, no replacement of image-area information is executed to continue the acquiring of current image-area information and thereafter, the operation is routed to step 412. Then, in step 412, upon executing various image processing through the processing methods shown in FIGS. 13A and 13B, the operation is routed to step 413. In step 413, the image signal is outputted and, then, the operation is routed back to step 302.

Thus, with the fourth embodiment, due to the provision of the image conversion processing section connected in a preceding stage of the image signal output section, the fourth embodiment has, in addition to the same advantages as those of the first embodiment, another advantage in which it becomes possible to provide the driver with a display of an image with a further excellent visibility.

Also, while the first to fourth embodiments have been described with reference to exemplary structures wherein each of the camera modules (image pickup systems) is constituted by three image pickup sections, it does not matter if the number of pieces of the image pickup sections lies in a desired number of plural pieces.

Further, the first to fourth embodiments have been exemplarily described with reference to a structure with the number of camera module being shown in a single piece, it is not objectionable for the desired number of plural camera modules to be mounted onto a moving object. Additionally, while the first to fourth embodiments have been exemplarily shown for square-shaped image area selection, it is, of course, to be appreciated that the image area selection may be executed in an arbitrary shape.

The entire content of Japanese Patent Application No.

P2003-358693 with a filing data of Oct. 20, 2003 is herein incorporated by reference.

Although the present invention has been described above by reference to certain embodiments of the invention, the invention is not limited to the embodiments described above and modifications will occur to those skilled in the art, in light of the teachings. The scope of the invention is defined with reference to the following claims.

1. An image pickup device adapted to be mounted on a moving object for picking up an image on a surrounding area during traveling of the moving object, comprising:
an image pickup system having a plurality of lens components and a plurality of image receiver sections located in correspondence to the plurality of lens components;
a control signal input section inputting a control signal commanding the image pickup system to execute image pickup operation;
an image-area selecting section responsive to the control signal inputted from the control signal input section to select a preset image area from image areas picked up by the image pickup system; and
an image signal output section outputting an image signal indicative of an image area selected from the image-area selecting section.

2. The image pickup device according to claim 1, further comprising:
an image structuring section synthesizing a plurality of image-area information corresponding to the plurality of image receiver sections into a single image area information.

3. The image pickup device according to claim 1, further comprising:
an image-area computing section responsive to the control signal inputted from the control signal input section for computing the preset image area.

4. The image pickup device according to claim 1, further comprising:
an image processing section executing image processing for improving a visibility prior to outputting the image signal delivered from the image signal output section.

5. The image pickup device according to claim 1, wherein:
the plurality of lens components include non-wide-angle pickup lens.

6. The image pickup device according to claim 1, wherein:
the image pickup system includes a multifaceted-eye type camera module.

7. The image pickup device according to claim 1, wherein:
the control signal input section sets the control signal in response to a traveling direction and a speed of the moving object.

8. The image pickup device according to claim 1, wherein:
the control signal input section allows a driver of the moving object to manually set the control signal.

9. The image pickup device according to claim 1, wherein:
the image-area selecting section selects pixel information for an image area corresponding to image-receiver-section information and image-area information inputted from the control signal input section.

10. The image pickup device according to claim 2, wherein:
the image-area selecting section selects a plurality of image areas corresponding to the plurality of image receiver sections, and the image structuring section synthesizes the plurality of image-area information into the single image area information.

11. The image pickup device according to claim 3, wherein:
the image-area computing section calculates pixel information in correspondence to image-direction information and image-area-attachment information inputted from the control signal input section.

12. An image pickup device adapted to be mounted on an automobile for picking up an image on a surrounding area during traveling of the moving object, comprising:
an image pickup system including a plurality of lens components and a plurality of image receiver sections disposed in correspondence to the plurality of lens components;
a control signal input section for inputting a control signal commanding the image pickup system to execute image pickup operation;
an image-area selecting section responsive to the control signal inputted from the control signal input section to select a preset image area from image areas picked up by the image pickup system; and
an image signal output section for outputting an image signal indicative of an image area selected from the image-area selecting section.

13. An image pickup device adapted to be mounted on a moving object for picking up an image on a surrounding area during traveling of the moving object, comprising:
image pickup means having a plurality of lens components and a plurality of image receiver means located in correspondence to the plurality of lens components;
control signal input means inputting a control signal commanding the image pickup system to execute image pickup operation;
image area selecting means responsive to the control signal inputted from the control signal input means to select a preset image area from image areas picked up by the image pickup means; and
image signal output means outputting an image signal indicative of an image area selected from the image area selecting means.

14. An image pickup device adapted to be mounted on an automobile for picking up an image on a surrounding area during traveling of the automobile, comprising:
image pickup means including a plurality of lens components and a plurality of image receiver means disposed in correspondence to the plurality of lens components;
control signal input means for inputting a control signal commanding the image pickup means to execute image pickup operation;
image area selecting means responsive to the control signals inputted from the control signal input means to select a preset image area from image areas picked up by the image pickup means; and
image signal output means for outputting an image signal indicative of an image area selected from the image area selecting means.
